(19) United States
(12) Patent Application Publication
(10) Pub. No.: US 2006/0205109 A1
(43) Pub. Date: Sep. 14, 2006

(54) Method and apparatus for fabricating nanoscale structures

(76) Inventors: David Christopher Cox, Camberley (GB); Roy Duncan Forrest, Guildford (GB); Sembukutiarachilage Ravi Silva, Camberley (GB)

Correspondence Address: ROTHWELL, FIGG, ERNST & MANBECK, P.C., 1425 K STREET, N.W., SUITE 800, WASHINGTON, DC, 20005, US

(21) Appl. No.: 10/547,148

(22) PCT Filed: Mar. 1, 2004
(86) PCT No.: PCT/GB04/00849

§ 371 Date: Apr. 7, 2006

(30) Foreign Application Priority Data
Feb. 28, 2003 (EP) 0304623.2

(51) Int. Cl. H01L 51/40; H01L 29/06

(52) U.S. Cl. 438/99; 257/9

(57) ABSTRACT

An apparatus comprises a scanning electron microscope (SEM) (1) positioned over a manipulation chamber (2) which houses a sample holder (3). The walls of the manipulation chamber (2) support two probes (4, 4a) and the sample holder (3) is able to hold a sample (5), such as carbon nanotubes (10a) carried on a substrate (10). The apparatus can selectively move and apply voltages and currents to the probe or probes (4, 4a) and sample holder (3) under the SEM (1). By controlling the current that is passed across a contact between the probe (4) and a carbon nanotube (10a), a conditioned weld is formed. Likewise, by controlling the current that is passed along a carbon nanotube (10a), the nanotube (10a) can be annealed. Using both the probes (4, 4a) a carbon nanotube can be held and cut at any position along its length. This allows the formation of novel carbon nanotube structures.

### FIELD OF THE INVENTION

This invention relates to a method and apparatus for fabricating nanoscale structures. More specifically, the invention concerns a method of welding a nanoscale wire to a structure, a method of annealing a nanoscale wire and a method of cutting a nanoscale wire, along with apparatus for carrying out the methods and the nanoscale structures that can be produced by the methods.

### BACKGROUND OF THE INVENTION

The potential for nanoscale structures to be fabricated from nanoscale wires is being very actively researched. Nanoscale wires and, in particular, carbon nanotubes, have interesting properties and the potential to form a vast array of nanoscale electromechanical devices. For example, the small size (down to diameters of a few nanometres); ability to tolerate high electric current density; and semi-conducting or metallic electrical characteristics of carbon nanotubes make them ideal candidates as key elements in the next generation of electronic devices. However, carbon nanotubes are presently grown in bulk, either on substrates or as tangled bundles. This imposes severe limitations on the fabrication of specific devices or structures from carbon nanotubes. Consequently, a significant proportion of research into these materials has concentrated on applications suited to these production methods, such as their use for reinforcing materials; providing embedded conductive fibres in polymers; or their use in field emission tip arrays for flat panel displays.

The ability to position individual carbon nanotubes at chosen locations and selectively create electronically reliable nanotube to nanotube, or nanotube to substrate junctions has not yet been demonstrated. The limited number of electronic devices formed from carbon nanotubes up to now largely rely on scattering many nanotubes onto suitable substrates, followed by laying down conventional electrical contacts and then searching for the correct combination and/or orientation of nanotubes to constitute a rudimentary device. So, there is a need to develop ways for nanotube devices to be fabricated in a controlled and selective manner and to be manipulated to produce custom built electronic devices. This may enable them to become the basis of future electronic devices. At the same time, it is desirable for this to be made possible using fibres grown using existing growth techniques.

### SUMMARY OF THE INVENTION

According to a first aspect of the present invention, there is provided a method of welding a nanoscale wire to a structure, the method comprising:

positioning the nanoscale wire and the structure in contact with one another; and

applying a voltage across the contact so that a current flows through the contact and heats it to weld the wire to the structure.

According to a second aspect of the present invention, there is provided an apparatus for welding a nanoscale wire to a structure, the apparatus comprising:

a manipulator for positioning the nanoscale wire and the structure in contact with one another, and

a controller for applying a voltage across the contact so that a current flows though the contact and heats it to weld the wire to the structure.

So, a nanoscale wire, such as a carbon nanotube, and another structure, such as the probe of a manipulator, can be brought into contact with one another and, by passing a current between the wire and the structure, through the contact, a weld can be formed. The applicants have recognised that, usually, the electrical resistance of the contact is initially higher than the resistance of the wire or the other structure. Thus, when a current is passed across the contact between the wire and the structure, the contact is heated by the current more than the wire or the other structure and a weld is formed.

The invention allows a weld to be formed without damage to the wire or the other structure. However, in order to reduce the risk of the wire or the other structure being damaged during welding, it is preferred to limit the current that flows through the contact during welding. In other words, the controller preferably limits the current that flows through the contact during welding. Indeed, the current may be limited to below a welding current threshold. This is typically set lower than the typical current that can be carried by the particular type of nanoscale wire being welded before it overheats and either fails or is structurally damaged. This can be established by experiment. Usually, the welding current limit is in the order of 10 μA, although this depends greatly on the type of wire.

A voltage of less than around 5 V is usually sufficient to generate the required current. In one example, the voltage can be applied across the contact just once. Similarly, the current may be held steady for a predetermined period of time, e.g. between around is and around 100 s. This might be useful when experiments have established the current and duration required to obtain an optimum weld. However, it is preferred that a voltage is applied across the contact more than once. In other words, a voltage may be applied across the contact during plural separate intervals. So, the apparatus may comprise a controller for applying a voltage across the contact during plural separate intervals.

The applicants have recognised that this repeated application of the voltage conditions the weld and allows its quality to be monitored during formation. More specifically, by repeatedly applying a known voltage or voltage wave-form across the contact and measuring the current in successive applications, it is possible to detect reductions in the resistance of the contact. Reducing resistance can be indicative of improved electrical and mechanical properties of the weld. Furthermore, the applicants have recognised that when the resistance stops falling, the weld has reached optimum quality.

So, it is preferred that the method comprises monitoring the current passing through the contact while the voltage is applied. In other words, it is preferred that the controller monitors the current passing through the contact while the voltage is applied. It is also preferred that the method comprises comparing the current when a known voltage is applied with the current at that voltage when it is applied again. In other words, it is preferred that the controller compares the current when a known voltage is applied with the current at that voltage when it is applied again. Thus the change in resistance of the contact can be monitored. The comparison may be between voltages applied during different intervals, e.g. between succeeding applications of the voltage. However, it is preferred that the voltage is increased and decreased during each individual interval and the current at a voltage during the increase is compared with the current at that voltage during the decrease. To improve accuracy, the current can be compared at plural respective voltages or a voltage-current relationship can be compared.

As mentioned above, when no further substantial fall in resistance is detected, the weld can be considered to be optimum. It is therefore preferred the method comprises continuing to apply the voltage across the contact (e.g. applying the voltage during another interval) until the comparison shows that there is no substantial difference in current. In other words, the apparatus may comprise the controller continuing to apply a voltage across the contact (e.g. applying the voltage during another interval) until the comparator shows that there is no substantial difference in current. This might be when the difference in current is less than a pre-set limit, e.g. 1%.

As mentioned above, the other structure might typically be a probe for manipulating a nanoscale wire, e.g. a nanoscale probe. However, the other structure can be a variety of other devices or components. For example, the other structure may be a substrate for a nanoscale wire. Alternatively, it may be another nanoscale wire. So, the ability of the invention to weld nanoscale wires to a variety of other structures, including other nanoscale wires, and condition the welds to form optimised electrical and mechanical connections, allows a large number of new nanoscale structures to be formed. According to a third aspect of the present invention, there is therefore provided a nanoscale structure produced using the above methods. These structures can take a variety of different forms, but are characterised by including one or more welds formed using the above methods.

When the other structure is a moveable probe, once the nanoscale wire has been welded to the probe, the probe can be moved to move the wire or to exert strain on it. As the weld is mechanically strengthened by the conditioning, relatively large forces can be applied by the probe without the weld breaking. Furthermore, as the weld has good electrical characteristics, relatively large currents can be passed through the nanoscale wire. The applicants have recognised that this can allow the electrical and mechanical characteristics of the nanoscale wire itself to be improved by annealing. In other words, the structure may be a probe and the method may comprise passing a current along the wire via the probe sufficient to heat the wire and cause annealing. Similarly, the structure may be a probe and the controller may pass current along the wire via the probe sufficient to heat the wire and cause annealing.

The applicants believe this to be new in itself and, according to a fourth aspect of the present invention, there is provided a method of annealing a nanoscale wire, the method comprising welding a probe to the wire and passing current along the wire via the probe sufficient to heat the wire and cause annealing.

Likewise, according to a fifth aspect of the present invention, there is provided an apparatus for annealing a nanoscale wire, the apparatus comprising means for welding a probe to the wire and a controller for passing a current along the wire via the probe sufficient to heat the wire and cause annealing.

So, simply heating the wire can anneal it and improve its electrical and mechanical characteristics. However, moving the probe can exert strain on the wire to straighten or bend the wire during annealing. It is therefore preferred that the method includes moving the probe to exert strain on the wire. The probe may exert strain on the wire by bending the wire. Alternatively, the probe may exert strain on the wire by straightening the wire.

Once the nanoscale wire has been welded and/or conditioned, it may be desirable to cut it. For example, the nanoscale wire may be attached to a substrate from which it is desirable to free it. It is therefore preferred that the method further comprises:

positioning a cutting probe at a position along the length of the wire intermediate two positions at which the wire is held; and

applying an electrical potential between the cutting probe and the wire to cut the wire at the position along the length of the wire.

Likewise, it is preferred that the apparatus further comprises a manipulator for positioning a cutting probe at a position along the length of the wire intermediate two positions at which the wire is held and that the controller applies an electrical potential between the cutting probe and the wire to cut the wire at the position along the length of the wire.

The applicants believe this to be new in itself and, according to a sixth aspect of the present invention, there is therefore provided a method of cutting a nanoscale wire, the method comprising:

positioning a cutting probe at a position along the length of the wire intermediate two positions at which the wire is held; and

applying an electrical potential between the cutting probe and the wire to cut the wire at the position along the length of the wire.

Likewise, according to a seventh aspect of the present invention, there is provided an apparatus for cutting a nanoscale wire, the apparatus comprising:

a manipulator for positioning a cutting probe at a position along the length of the wire intermediate two positions at which the wire is held; and

a controller for applying an electrical potential between the cutting probe and the wire to cut the wire at the position along the length of the wire.

One of the two positions might be the position at which the wire is welded to the structure. The other of the two positions might be the point at which the wire contacts a substrate, e.g. on which it was grown. Typically, the cutting probe is positioned to touch the wire at the position along the length of the wire and the electrical potential is applied only between the cutting probe and one of the two positions at which the wire is held. This results in an electric current flowing only in a portion of the wire between the position that the cutting probe touches the wire and the one of the two positions. So, only that portion of the wire is heated and cut away from the remaining portion. To achieve this, the current is typically relatively high. For example, the applied potential can be controlled to pass a current exceeding the estimated typical current at which the nanoscale wire fails or is structurally damaged.

Alternatively, the cutting probe can be positioned so that it is closest to the wire at the position along the length of the wire, but slightly spaced away from the wire. When the electric potential is applied, the wire is then vaporised at the position along the length of the wire by the electric field between the wire and the probe. In this case, it is preferred that the applied electrical potential is alternated.

The ability of the invention to weld, anneal and cut nanoscale wires allows a large number of new nanoscale structures to be formed. According to an eighth aspect of the present invention, there is therefore provided a nanoscale structure produced using any of the above methods.

The methods of the present invention may be implemented at least partially using software e.g. computer programs. According to further aspects of the present invention, there is therefore provided computer software specifically adapted to carry out the methods described above when installed on a computer. The invention also extends to a computer software carrier comprising such software. The computer software carrier could be a physical storage medium such as a ROM chip, CD ROM or disk, or could be a signal such as an electronic signal over wires, an optical signal or a radio signal such as to a satellite or the like.

Nanoscale is intended to mean having at least one dimension measuring between 1 nm and 1 μm. For example, the diameter of a nanoscale wire might be between 1 nm and 1 μm. Indeed, it is preferred that the nanoscale wire(s) mentioned above are carbon nanotube(s) and these typically have diameters up to around 100 nm. However, the invention is not limited to carbon nanotubes. Rather, the nanoscale wire(s) may be nanofibre(s), nano-powder(s), nano-particle(s), nano-rod(s), nano-structure(s), carbon sphere(s) and single crystal nanowire(s). Likewise, the wire may be on a larger micron or millimetre scale. Whilst these nanoscale wire(s) and such like should be conductive, they may be inorganic or organic. Examples of suitable inorganic materials might be carbon or silicon. Organic materials might include conductive polymers or protein based fibres such as DNA, enzymes or micro channels.

Reference to carbon nanotubes is not limited to carbon nanotubes produced by any particular method, and as such, nanotubes produced by any recognised method described in the literature can be manipulated by the methods of the invention. It should also be understood that the carbon nanotubes referred to in this specification may be either single wall or multi-wall nanotubes; that is they may be considered to be constructed from one or more concentric layers of graphitic carbon material. They may also be Silicon nanowires or any other nano/micro wire composed of inorganic conducting material.

Preferred embodiments of the invention are now described, by way of example only, with reference to the accompanying drawings.

### BRIEF DESCRIPTION OF THE DRAWINGS

FIG. 1 is a schematic illustration of an apparatus according to the present invention;

FIG. 2 is a schematic illustration of a method of welding a carbon nanotube to a probe using the apparatus of FIG. 1;

FIG. 3 is a loglinear graph of current versus voltage during welding;

FIG. 4 is a schematic illustration of a method of cutting a carbon nanotube using the apparatus of FIG. 1; and

FIG. 5 is a schematic illustration of a method of welding a carbon nanotube to another carbon nanotube using the apparatus of FIG. 1.

### DETAILED DESCRIPTION OF THE PREFERRED EMBODIMENTS

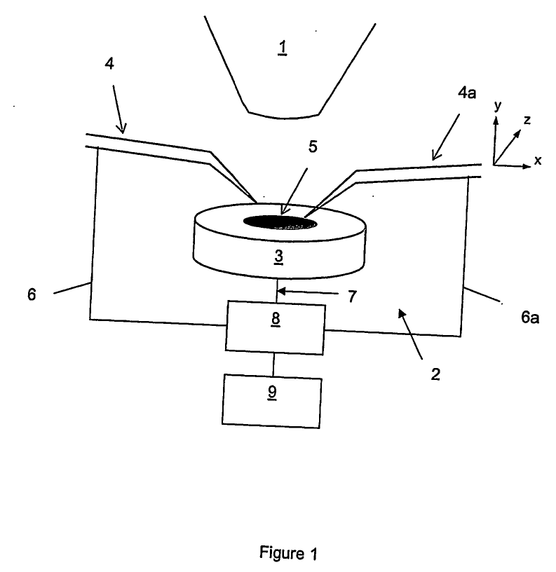

Referring to FIG. 1, an apparatus comprises a scanning electron microscope (SEM) 1 positioned over a manipulation chamber 2 (or SEM chamber) which houses a sample holder 3 (or SEM stage). The walls of the manipulation chamber 2 support two probes 4, 4a and the sample holder 3 is able to hold a sample 5, such as carbon nanotubes 10a carried on a substrate 10 or arranged on a support. In other embodiments, more than two probes 4, 4a are provided and the probes 4, 4a are supported on the sample holder 3 (or SEM stage).

In this embodiment, the probes 4, 4a each comprise sharp implements or manipulators having tip radius in the range around 5 nm to around 100 μm. In other embodiments, the probes 4, 4a are hook-shaped. The electrical, physical and mechanical properties of tungsten make it a particularly suitable material for the probes 4, 4a. However, the probes 4, 4a can be made from metals other than tungsten. Indeed, they can be made from any electrically conducting material. Alternatively, they can be oxide-coated or semi-conducting to allow more extensive evaluation of the electrical properties of the nanotubes.

The probes 4, 4a are electrically isolated from the manipulation chamber 2, each other and sample holder 3, but connected to external wires 6, 6a passing through the wall of the manipulation chamber 2. Likewise, the sample holder 3 is arranged to electrically isolate the sample 5 from the manipulation chamber 2 and the probes 4, 4a, but connect it to an external wire 7 passing through the wall of the manipulation chamber 2. The purpose of the electrical connections is to allow electric potential to be applied to the probes 4, 4a and the sample holder 3; and to allow electric current to be passed through circuits formed between the probes 4, 4a and the sample holder 3, e.g. via the sample 5.

For this purpose, a power supply 8 is connected to the external wires 6, 6a, 7. The power supply 8 is capable of selectively applying electric potential between any combination of wires 6, 6a, 7 and hence any combination of probes 4, 4a and/or the sample holder 3. So, the power supply 8 is connected to a power source (not shown) and includes switches for making connections between the power source and the different wires 6, 6a, 7. The power supply 8 can also variably and selectively limit the current that flows in any circuit formed by the probes 4, 4a and/or the sample holder, e.g. via the sample 5. In other words, the wires 6, 6a and 7 can provide a potential difference and/or current at either probe 4, 4a to probe 4, 4a or probe 4, 4a to sample holder 3. The voltage that the power supply 8 can provide is substantially within the range around −50 V to around +50 V. The electric current that the power supply 8 can provide is substantially within the range around 1×10⁻¹² A to around 1 A.

The probes 4, 4a are capable of movement by translation in three-axes (x, y, z). Similarly, the sample holder 3 is capable of movement by translation in three-axes (x, y, z) and tilting and rotation. In other embodiments different or additional types of movement can be provided for both the probes 4, 4a and the sample holder 3. The probes 4, 4a and sample holder 3 can be moved with nanometre precision over a total range up to between around 10 μm to around 10 mm. In this embodiment, movement is achieved using piezoelectric actuators, although, in other embodiments, other types of mechanical and electrical actuators can be used.

A control unit 9 is arranged to control the power supply 8 and movement of the probes 4, 4a and sample holder 3 using the actuators. In this embodiment, the controller 9 is a computer that runs software adapted to carry out the methods described below and has an interface for controlling the power supply 8 and actuators. As well as controlling the power supply 8, the controller 9 is able to monitor the potential difference and current generated by the power supply 8. Similarly, as well as controlling movement of the probes 4, 4a and the sample holder 3, the controller 9 is able to control the SEM 1 and use image analysing software to analyse the image generated by the SEM 1 and monitor movement of the probes 4, 4a, sample holder 3 and even the individual carbon nanotubes 10a, as described in more detail below.

The carbon nanotubes 10a can be prepared in a variety of ways and the sample 5 may therefore have one of several different forms. For example, the carbon nanotubes 10a can be: attached to a Up that has been dipped into a bundle of carbon nanotubes 10a; embedded in a conducting polymer sample which has been cleaved to expose the carbon nanotubes 10a; or prepared using any other method that produces a sample 5 allowing the carbon nanotubes 10a to be brought into electrical contact between the probes 4, 4a or between one or both of the probes 4, 4a and the sample holder 3. Indeed, the invention is applicable to nanoscale wires other than carbon nanotubes, but these should be conductive and, if attached to a substrate 10, it is useful if that too is conductive. However, the embodiments below are described in relation to a sample 5 comprising carbon nanotubes 10a attached to catalytic particles forming a substrate 10 from which the nanotubes 10a have grown.

So, the apparatus can selectively move and apply voltages and currents to the probe 4, 4a or probes 4, 4a and sample holder 3 under the SEM 1. This allows an individual carbon nanotube 10a to be selected, welded to other structures such as the probe(s) 4, 4a, substrate 5 or another carbon nanotube 10a, or cut at a selected position along its length. These individual processes are described more fully below.

Selection of a Carbon Nanotube

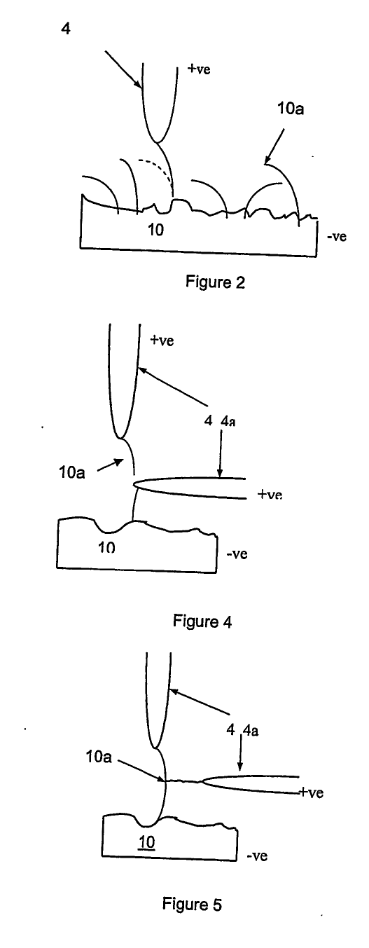

Referring to FIG. 2, the sample 5 comprising a substrate 10 to which several carbon nanotubes 10a are attached is held in the sample holder 3. The probe 4 can be moved relative to the sample holder 3 and hence relative to the carbon nanotubes 10a.

The controller 9 first focuses the SEM 1 in the plane of an end of a target carbon nanotube 10a distal to the substrate 10. The probe 4 is then moved into the same plane as the end of the carbon nanotube 10a and translated in that plane (the x, z plane in FIG. 1) toward the carbon nanotube 10a. Once this rough alignment has been carried out, the controller causes the power supply to apply a selection voltage substantially in the range of around 1 V to 2 V to the probe 4, with the substrate 10 and nanotube 10a being held at ground, e.g. 0 V. At the same time, the controller 9 causes the power supply 8 to limit the current that is able to flow between the probe 4 and the sample holder 3, e.g. via any of the nanotubes 10a or the substrate 10, to below a selection current limit, e.g. substantially less than around 1 μA. The purpose of the selection voltage is to cause electrostatic attraction between the probe 4 and the target nanotube 10a. The purpose of the current limit is to ensure that, should the probe 4 contact any of the nanotubes 10a, the current is insufficient to cause significant damage to the nanotube 10a, e.g. by heating it enough to vaporise it.

The depth of field of the SEM 1 may be as deep as 500 nm. So, using the depth of field of the SEM 1 may only allow the probe 4 and the target carbon nanotube 10a to be positioned within around 500 nm of each other. Once the probe is in the same depth of field as the target carbon nanotube 10a, the controller 9 therefore causes the probe 4 to move in discrete steps toward the nanotube 10a. At the same time, the controller 9 monitors the position of the nanotube 10a using the image produced by the SEM 1. When the gap between the probe 4 and the target nanotube 10a is small enough, electrostatic attraction will bend the nanotube 10a toward the probe 4. This enables the approach of the probe 4 to be carefully monitored.

As the nanotube 10a is bent toward the probe 4, the controller 9 monitors the current flowing between the probe 4 and the sample holder 3. When the probe 4 is close enough and the nanotube 10a bends sufficiently, the nanotube 10a will contact the probe 4. Before contact is made, substantially no current flows between the probe 4 and the sample holder 3. However, when the nanotube 10a and probe 4 make contact, current flows between the probe 4 and the sample holder 3. As the controller 9 monitors the current, the controller 9 can identify the precise moment that contact is made between the probe 4 and the nanotube 10a and, when contact is identified, the controller stops moving the probe 4 relative to the substrate 10. The selection voltage applied to the probe 4 can also be stopped or reduced. The target nanotube 10a has now been selected.

Once the nanotube 10a has been selected, the electrical properties (e.g. semi-conducting or metallic) of that particular nanotube 10a are determined by applying a known voltage between the probe 4 and the sample holder 3 and measuring the current that flows. This can help determine the quality of the nanotube 10a and its usefulness for a particular application. If a nanotube 10a is not suitable, the contact can be broken, e.g. by increasing the current to vaporise the nanotube 10a or just by withdrawing the probe 4, and an alternative nanotube 10a can be selected.

Welding a Nanotube to a Probe

Once a nanotube 10a has been selected and the nanotube 10a has been deemed suitable, a current can be passed through the nanotube 10a to heat the nanotube 10a and, more importantly, its connection to the probe 4. This welds the nanotube 10a to the probe 4, improving the electrical and mechanical contact between the nanotube 10a and the probe 4.

More specifically, before a nanotube 10a is selected for welding, the current at which the nanotubes 10a of a particular sample 5 fail, e.g. by over-heating and vaporisation, is determined. In this embodiment, this is achieved by the controller 9 selecting a nanotube 10a of the sample 5 and, once contact has been established, causing the power supply 8 to gradually increase the current flowing through the nanotube 10a until it fails. When it fails, the current drops sharply to zero. The controller 9 monitors the current and determines the maximum current flowing though the nanotube 10a, which is usually just before the nanotube 10a fails or becomes structurally damaged. This is called the failure current. The process is usually repeated for two or more nanotubes 10a and a welding current limit is set below a typical (e.g. the lowest or average) determined failure current. Of course, once significant experience has been gained with a particular type or batch of samples 5, the welding current limit can be reliably determined and it is not necessary to set a new limit for every sample 5.

When a nanotube 10a is selected, as described above, the small current that flows at the moment that contact is made heats the nanotube 10a in the area of the contact. More specifically, as the contact between the nanotube 10a and the probe 4 is initially electrically poor, e.g. has high resistance, in comparison to the rest of the nanotube 10a, and indeed the probe 4 and substrate 10, this region is heated to a higher temperature than the rest of nanotube 10a. This results in a small amount of diffusion of material between the nanotube 10a and the probe 4 at the contact. However, as the current limit during selection is very low, the heating and diffusion at the contact is minimal and the electrical connection remains poor.

So, once the nanotube 10a has been selected and contact been made, the contact is welded to improve the connection. This is achieved by increasing or “ramping” the voltage across the contact, e.g. between the probe 4 and the sample holder 3, in a controlled manner and allowing the current to rise to the welding current limit. In one embodiment, the controller 9 causes the power supply 8 to increase the current and to hold it at a steady level for a predetermined duration, which can be substantially between around 1 s and 100 s. The current heats the contact between the nanotube 10a and the probe 4 resulting in further diffusion of material between the nanotube 10a and the probe 4 (e.g. “inter-diffusion”). The weld that is formed therefore has improved electrical and mechanical properties.

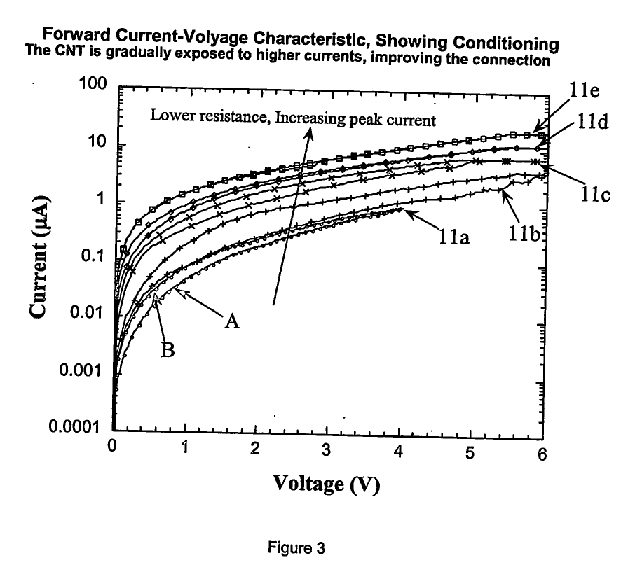

In another embodiment, the controller 9 causes the power supply 8 to repeatedly apply a voltage across the contact, e.g. between the probe 4 and the sample holder 3. More specifically, the voltage is increased and then decreased over a short period of time on more than one separate occasion. By monitoring the current as the voltage is increased and decreased, it is possible to see the improvement in quality of the electrical connection, e.g. as its resistance is lowered. In other words, whilst the flow of current causes heating that improves the contact, the resistance across the contact changes during application of the voltage. So, referring to FIG. 3, a plot of current to voltage shows a different curve as the voltage is increased (e.g. curve A) in comparison to when it is decreased (e.g. curve B) for each voltage application (11a-e). However, when there is no longer any improvement of the electric connection of the contact, the resistance does not change significantly and the curve as the voltage is increased is virtually the same as the curve as the voltage is decreased (see, e.g. curve lie in FIG. 3) So, the first step is for the controller 9 to establish that contact has been made by causing the power supply 8 to apply a low voltage, e.g. ±1 V, across the contact and detecting whether or not any current, e.g. around a few nA, flows across the contact. If a current flows, the controller 9 determines that contact between the probe 4 and the nanotube 10a has been made. This is effectively the same step as confirming contact has been made with a target nanotube 10a during selection, as described above. If no current flows, the process of selecting a nanotube 10a is repeated.

Next, the controller 9 causes the power supply to increase the voltage between the probe 4 and the sample holder 3. In this embodiment, the controller 9 increases the voltage in steps, e.g. of around 0.1 V. The current is held at each step, e.g. for around a few ms or more. Each time the voltage is increased, the current is measured.

While the voltage Is increased, the controller 9 causes the power supply 8 to limit the current to the welding current limit. Typically, this limit is no greater than around 1 μA. Likewise the controller 9 limits the voltage to a welding voltage limit. The welding voltage limit is typically around a few volts. So, the controller 9 causes power supply to stop increasing the voltage when either the welding current limit is reached or the welding voltage limit is reached. When the current limit or the voltage limit is reached, the controller 9 causes the power supply 8 to decrease the voltage in steps, e.g. of around 0.1 V, back to 0 V. Again, each time the voltage is decreased, the current is measured. This increase and decrease of voltage can be referred to as a conditioning cycle.

Following or during each conditioning cycle, the controller 9 determines the quality of the contact. This is achieved by the controller 9 comparing the current measurements as the voltage is/was increased during the conditioning cycle with respective current measurements as the voltage is/was decreased during the conditioning cycle. Comparison at one selected voltage is sufficient. However, to improve accuracy, several comparisons are made or the current-voltage curve as the voltage is/was increased is compared to the current voltage curve as the voltage is/was decreased. As can be seen in FIG. 3, if the contact is poor, then significant differences are seen on the increasing and decreasing curves, e.g. there is hysteresis. However, if the contact is good, the resistance of the contact is not improved over the conditioning cycle and there is no substantial difference on the increasing and decreasing data curves.

So, if there is more than a pre-set difference, e.g. 1%, between the current at respective (or coincident) voltages during increasing and decreasing phases of the cycle, the controller 9 performs another conditioning cycle. Alternatively, if the controller 9 determines that there is no or less than the pre-set difference between the two currents or sets of currents, then it determines that the electrical connection of the contact is good. The controller 9 does not then perform any further conditioning cycles.

If the controller 9 determines that another conditioning cycle should be performed, it also determines whether the voltage limit was reached or whether the current limit was reached to cause it to stop increasing the voltage in the previous conditioning cycle. If the voltage limit was reached, the voltage limit is increased, e.g. by around 1 V. If the current limit was reached, the current limit is increased, e.g. by around 1 μA. The next conditioning cycle is then performed using the higher voltage or current limit, with the result that a higher current is passed across the contact.

The controller 9 continues to perform conditioning cycles in this manner until it determines that the quality of the contact is no longer improving, e.g. that there is less than say a 1% difference in the current at the respective (or coincident) voltage(s) during the increasing and decreasing phases of the cycle. This allows improvement to the contact between the nanotube 10a and the probe 4 while ensuring that the current flow is under strict control and excessive current heating does not damage the nanotube 10a. Furthermore, the controlled application of the voltage enables a conditioned weld to be established quickly and safely.

Conditioning a Nanotube

In a manner similar to that used for conditioning welds it is possible to condition an individual nanotube 10a. For example, when nanotubes 10a are grown at low temperature by catalytic methods it is known that they often contain curls and kinks. It is possible to straighten these curls and kinks and perform other types of conditioning using the present invention.

When a nanotube 10a, which is connected to its substrate 10 in the sample holder 3, has been welded to the probe 4 using the above method, it is securely held at each end and there is a good electrical connection at each end. Relatively high currents can therefore be passed along the nanotube 10a without the probe 4/nanotube 10a or nanotube 10a/substrate 10 contact being damaged. Furthermore, the probe 4 can be moved relative to the sample holder 3 to exert mechanical strain on the nanotube 10a.

For example, if the nanotube 10a is curved, once it has been welded to the probe 4, the controller 9 moves the probe 4 away from the substrate 10. This straightens the nanotube 10a. The controller 9 then causes the power supply 8 to pass current through the nanotube 10a to heat the nanotube 10a for a fixed duration. This anneals the nanotube 10a, so that its structure becomes straighter. Indeed, the controller 9 can pass current though the nanotube 10a to cause heating at the same time as progressively moving the probe 4 away from the sample holder 3. Thus, a significant amount of straightening can be achieved.

In another embodiment, the controller 9 moves the probe 4 to induce curves in a straight nanotube 10a. This can cause the nanotube 10a to develop particular electrical characteristics, such as quantum dots.

In another embodiment, the controller 9 heats the nanotube by varying the applied voltage in a way similar to during a conditioning cycle for a weld, as described above. In other words, the controller 9 increases and decreases the voltage whilst monitoring the current and repeats this until it determines that the electrical characteristics of the nanotube 10a are no longer improving. Thus, reliable improvements in the electrical characteristics of the whole nanotube 10a can be achieved. Of course, the probe 4 can also be moved before or during application of the voltage(s) to straighten or bend the nanotube as desired.

So, it is possible to both improve the electrical behaviour or characteristics of nanotube 10a without straightening or bending the nanotube 10a, or to move the probe 4 relative to the sample holder 3 to exert strain on the nanotube and improve the electrical behaviour while straightening or bending the nanotube 10a to some extent.

Cutting a Nanotube

Once a nanotube 10a has been welded to the probe 4, it is useful to be able to either cut the nanotube 10a somewhere along its length or at the end at which it is attached to the substrate 10. To achieve this, the second probe 4a, which is able to move independently of the first probe 4, is used.

Referring to FIG. 4, the controller 9 moves the second probe 4a toward the nanotube 10a at a point at which it is desired to cut the nanotube 10a. The controller 9 then causes the power supply to apply the selection voltage, e.g. around 1 V to 2 V, to the second probe 4a, whilst the first probe 4 and the substrate are held at ground voltage, e.g. 0V. This defines the point at which it is desired to cut the nanotube 10a . So, the selection process is effectively repeated, using the second probe 4a and the nanotube 10a already welded to the first probe 4.

If it is desired to keep the part of the nanotube 10a welded to the first probe 4, once contact has been established between the second probe 4a and the nanotube 10a, the controller 9 causes the power supply 8 to apply a voltage between second probe 4a and the sample holder 3 that causes the current in the portion of the nanotube 10a between the second probe 4a and the substrate 10 to exceed the failure current (e.g. apply a current usually around tens of μA to hundreds of μA). No current is passed though the portion of the nanotube 10a between the second probe 4a and the first probe 4. So, the portion of the nanotube 10a between the second probe 4a and the substrate 10 vaporises, leaving the portion of the nanotube 10a between the second probe 4a and the first probe 4 intact and still welded to the first probe 4a. By appropriate selection of the point at which the second probe 4a contacts the nanotube 10a, the nanotube 10a can therefore be cut at any desired point along its length. The nanotube 10a can then be moved freely, e.g. to another region of the sample 5 or to another substrate 10.

In another embodiment, a small gap can be left between the second probe 4a and the nanotube 10a. An alternating voltage is then applied between the second probe 4a and the nanotube 10a, which causes a small portion of the nanotube 10a nearest to the second probe 4a to vaporise. This results in two portions of the nanotube 10a remaining, one welded to the first probe. 4 and the other attached to substrate 10, as shown in FIG. 4.

As with the welding the nanotubes 10a and conditioning them, this process can be controlled by the controller 9. In the simplest case, the probe 4a can be positioned manually and the controller 9 used to control the voltage and current flow at each tip and substrate respectively. Alternatively, the controller 9 can use the image from the SEM 1 to position the probes 4, 4a and the whole cutting process can be automated. The controller 9 can offer significant improvements in both the speed and repeatability of the cutting and shortening processes.

Welding a Nanotube to another Structure

The welding process described above can be used equally well to weld a nanotube 10a to structures other than the probes 4, 4a. For example, a nanotube 10a can be welded to other nanotubes 10a (see, e.g. FIG. 5) or to other structures or substrates (not shown). Usually, the nanotube 10a is first welded to the first probe 4 and cut away from the substrate 10 using the above welding and cutting processes. The nanotube 10a then, in effect, becomes an extension of the probe 4. This means that it can be moved to touch other nanotubes 10a or substrates 10 and be welded to them using the welding process described above. Indeed, it is possible to weld nanotubes 10a end-to-end to create a longer nanotube from dissimilar nanotubes, and also weld nanotubes to the sides of other tubes to create nanotubes in ‘T’ formations, as shown in FIG. 5. Hence, nanotube devices with more than two terminals can be created. Single nanotubes or welded nanotube combinations can then be welded to other suitable structures or substrates, again using the methods described above. The only requirement is that the other structures or substrates are electrically conductive and can be connected to the power supply 8.

Using the techniques described above, it is possible to construct electronic devices based on carbon nanotubes 10a of considerably greater complexity than has been previously demonstrated. Similar or dissimilar nanotubes 10a can be welded together in a large variety of configurations, and to suitable substrates 10 that can be connected in turn to other devices, to produce carbon nanotube electronic devices (and related structures) selectively and with a high degree of success. Examples of other useful structures include high-aspect ratio extensions to scanning probe microscope tips, mechanical actuators in micro electrical machine system (MEMS) devices and sensors.

As the whole, the above nanotube selection, welding and cutting processes are based on the careful control of voltage and current flow and movement of the probes 4, 4a relative to the sample holder 3. The controller 9 uses the power supply 8 to control and monitor current and voltage. It also uses the SEM image and feedback from the actuators to establish the positions in three dimensional space of the probes 4, 4a, nanotubes 10a and substrate 10. The processes can therefore be fully or partially automated as desired.

The described embodiments of the invention are only examples of how the invention may be implemented. Modifications, variations and changes to the described embodiments will occur to those having appropriate skills and knowledge. These modifications, variations and changes may be made without departure from the spirit and scope of the invention defined in the claims and its equivalents.

1. A method of welding a nanoscale wire to a structure, the method comprising:
positioning the nanoscale wire and the structure in contact with one another; and applying a voltage across the contact so that a current flows through the contact and welds the wire to the structure.

2. The method of claim 1, further comprising limiting the current that flows through the contact during welding.

3. The method of claim 2, wherein the current is limited to a current threshold level lower than an estimated typical current at which the nanoscale wire fails or is structurally damaged.

4. The method of any of claim 1, wherein the current threshold level is less than around 10 μA.

5. The method of any, one of claim 1, wherein the voltage is less than around 5V.

6. The method of claim 1, comprising applying the voltage across the contact during plural separate intervals.

7. The method of claim 1, comprising monitoring the current during application of the voltage.

8. The method of claim 1, comprising comparing the current when a known voltage is applied with the current when that voltage is applied again to monitor the change in resistance of the contact.

9. The method of claim 8, comprising continuing to apply the voltage(s) across the contact until there is no substantial difference in the compared currents.

10. The method of claim 1, wherein the structure is a nanoscale probe.

11. The method of claim 1, wherein the structure is another nanoscale wire.

12. (canceled)

13. A method of annealing a nanoscale wire, the method comprising welding a probe to the wire and passing a current along the wire via the probe sufficient to heat the wire and cause annealing.

14. The method of claim 13, wherein the probe is movable and the method comprises moving the probe to exert strain on the wire during annealing.

15. The method of claim 14, comprising exerting strain on the wire by bending the wire.

16. The method of claim 14, comprising exerting strain on the wire by straightening the wire.

17. (canceled)

18. A method of cutting a nanoscale wire, the method comprising:
positioning a cutting probe at a position along the length of the wire intermediate two positions at which the wire is held; and
applying an electrical potential between the cutting probe and the wire to cut the wire at the position along the length of the wire.

19. The method of claim 18, wherein the cutting probe is positioned to touch the wire at the position along the length of the wire and the electrical potential is applied only between the cutting probe and one of the two positions at which the wire is held.

20. The method of claim 18, wherein the applied potential is controlled to pass a current exceeding an or the estimated current at which the nanowire fails or is structurally damaged.

21. The method of claim 18, wherein the cutting probe is positioned so that it is closest to the wire at the position along the length of the wire, but slightly spaced away from the wire.

22. The method of claim 21, wherein the applied electrical potential is alternated.

23. The method of claim 1, wherein the nanoscale wire is a carbon nanotube.

24. A nanoscale structure produced using the method of claim 1.

25. A nanoscale structure comprising two or more nanoscale wires welded together using the method of claim 1.

26. A nanoscale structure comprising a nanoscale wire annealed using the method of claim 13.

27. (canceled)

28. An apparatus for welding a nanoscale wire to a substrate, the apparatus comprising:
a manipulator for positioning the nanoscale wire and the structure in contact with one another; and
a controller for applying a voltage across the contact so that current flows through the contact during welding.

29. The apparatus of claim 28, wherein the controller limits the current that flows through the contact during welding.

30. The apparatus of claim 29, wherein the controller limits the current to a threshold level lower than an estimated typical current at which the nanoscale wire fails or is structurally damaged.

31. The apparatus of claim 29, wherein the current threshold level is less than around 10 μA.

32. The apparatus of claim 28, wherein the voltage is less than around 5V.

33. The apparatus of claim 28, wherein the controller applies the voltage during plural separate intervals.

34. The apparatus of claim 28, wherein the controller monitors the current during application of the voltage.

35. The apparatus of claim 28, wherein the controller compares the current when a known voltage is applied with the current when that voltage is applied again to monitor the change in resistance of the contact.

36. The apparatus of claim 35, wherein the controller continues to apply the voltage(s) across the contact until there is no substantial difference in the compared currents.

37. The apparatus of claim 28, wherein the structure is a probe for manipulating a nanoscale wire.

38. The apparatus of claim 28, wherein the structure is another nanoscale wire.

39. (canceled)

40. An apparatus for annealing a nanoscale wire, the apparatus comprising means for welding a probe to the wire and a controller for passing a current along the wire via the probe sufficient to heat the wire and cause annealing.

41. The apparatus of claim 40, comprising a manipulator for moving the probe to exert strain on the wire during annealing.

42. The apparatus of claim 40, wherein the manipulator moves the probe to exert strain on the wire by bending the wire.

43. The apparatus of claim 40, wherein the manipulator moves the probe to exert strain on the wire by straightening the wire.

44. (canceled)

45. An apparatus for cutting a nanoscale wire, the method comprising:
a manipulator for positioning a cutting probe at a position along the length of the wire intermediate two positions at which the wire is held; and
a controller for applying an electrical potential between the cutting probe and the wire to cut the wire at the position along the length of the wire.

46. The apparatus of claim 45, wherein the cutting probe is positioned to touch the wire at the position along the length of the wire and the controller applies the electrical potential only between the cutting probe and one of the two positions at which the wire is held.

47. The apparatus of claim 46, wherein the controller applies the electric potential so that a current is passed that exceeds a or the estimated typical current at which the nanoscale wire fails or is structurally damaged.

48. The apparatus of claim 45, wherein the manipulator positions the probe so that it is closest to the wire at the position along the length of the wire, but slightly spaced away from the wire.

49. The apparatus of claim 48, wherein the applied electrical potential is alternated.

50. The apparatus of claim 28, wherein the nanoscale wire is a carbon nanotube.

51. Computer software adapted to carry out the method of claim 1 when processed by a processor.

52. The computer software of claim 51 carried by a data carrier.

53. (canceled)

54. (canceled)

55. The method of claim 13, wherein the nanoscale wire is a carbon nanotube(s).

56. The method of claim 18, wherein the nanoscale wire is a carbon nanotube.

57. The apparatus of claim 40, wherein the nanoscale wire is a carbon nanotube.

58. The apparatus of claim 40, wherein the nanoscale wire is a carbon nanotube.

59. Computer software adapted to carry out the method of claim 13 when processed by a processor.

60. Computer software adapted to carry out the method of claim 18 when processed by a processor.
